(19) United States
(12) Patent Application Publication
(10) Pub. No.: US 2025/0221009 A1
(43) Pub. Date: Jul. 3, 2025

(54) SEMICONDUCTOR DEVICE INCLUDING AMORPHOUS BORON NITRIDE FILM AND METHOD OF MANUFACTURING THE AMORPHOUS BORON NITRIDE FILM

(71) Applicants: Samsung Electronics Co., Ltd., Suwon-si (KR); UIF (University Industry Foundation), Yonsei University, Seoul (KR)

(72) Inventors: Taejin CHOI, Suwon-si (KR); Hyungjun KIM, Seoul (KR); Hyeonjin SHIN, Suwon-si (KR); Inkyu SOHN, Seoul (KR); Sangyoon LEE, Seoul (KR); Seungmin CHUNG, Seoul (KR)

(73) Assignees: Samsung Electronics Co., Ltd., Suwon-si (KR); UIF (University Industry Foundation), Yonsei University, Seoul (KR)

(21) Appl. No.: 19/002,199

(22) Filed: Dec. 26, 2024

(30) Foreign Application Priority Data
Dec. 28, 2023 (KR) 10-2023-0195357

(51) Int. Cl. H10D 64/66; H10D 64/01

(52) U.S. Cl. CPC H10D 64/675; H10D 64/01

(57) ABSTRACT

A semiconductor device includes a semiconductor substrate, a source and a drain provided to be horizontally spaced apart from each other on the semiconductor substrate, a channel layer provided between the source and the drain, a gate insulating layer provided on the channel layer, a gate electrode provided on the gate insulating layer, and a spacer provided to surround the gate electrode, wherein the spacer includes an amorphous boron nitride film.

### CROSS-REFERENCE TO RELATED APPLICATION

This application is based on and claims priority under 35 U.S.C. § 119 to Korean Patent Application No. 10-2023-0195357, filed on Dec. 28, 2023, in the Korean Intellectual Property Office, the disclosure of which is incorporated by reference herein in its entirety.

### BACKGROUND

### 1. Field

The disclosure relates to a semiconductor device including an amorphous boron nitride film and a method of manufacturing the amorphous boron nitride film.

### 2. Description of the Related Art

Integrated circuits of various electronic devices including display devices, image sensors, field-effect transistors, memory elements, etc. may be manufactured by combining and connecting semiconductors, conductors, and insulators to one another. For example, integrated circuits of various electronic devices may be manufactured by forming a plurality of unit elements on a substrate and then stacking interlayer insulating films and wiring on them.

As the degree of integration of integrated circuits has increased significantly, the distance between conductor patterns has been gradually decreased. Accordingly, a parasitic capacitance between the conductor patterns has increased, which may deteriorate the performance of the electronic devices. For example, the parasitic capacitance may delay signal transmission in and/or between semiconductor devices. Methods for reducing the parasitic capacitance have been proposed.

### SUMMARY

Provided is a semiconductor device with reduced cross-talk.

Additional aspects will be set forth in part in the description which follows and, in part, will be apparent from the description, or may be learned by practice of the presented embodiments of the disclosure.

According to an aspect of the disclosure, a semiconductor device includes a substrate, a source and a horizontally spaced apart from each other on the substrate, a channel layer between the source and the drain, a gate electrode on the gate insulating layer, a gate insulating layer insulating the channel layer from the gate electrode, and a spacer surrounding the gate electrode, the spacer including an amorphous boron nitride film.

A dielectric constant of the amorphous boron nitride film may be 2.0 or less.

A carbon content of the amorphous boron nitride film may be 5 at % or less.

A boron-oxygen (B—O) content of the amorphous boron nitride film may be 1 at % or less.

The channel layer may be included in a plurality of channel layers, and the plurality of channel layers may be spaced apart from each other in a first direction perpendicular to the substrate.

Each of the plurality of channel layers may have a nanowire shape extending in a second direction different from the first direction.

Each of the plurality of channel layers may have a nanosheet shape.

The semiconductor device may further include conductive plugs respectively on the source and the drain.

The semiconductor device may further include contacts respectively connected to the source and the drain through the conductive plugs.

According to another aspect of the disclosure, a semiconductor device includes a substrate defining a trench, a source and a provided horizontally spaced apart from each other on the substrate such that the trench is between the source and the drain, a spacer covering a lower surface and a sidewall of the trench, the spacer including an amorphous boron nitride film, and a gate electrode inside the trench, the gate electrode contacting the spacer and filling a portion of the trench.

A dielectric constant of the amorphous boron nitride film may be 2.0 or less.

A carbon content of the amorphous boron nitride film may be 5 at % or less.

A B—O content of the amorphous boron nitride film may be 1 at % or less.

The semiconductor device may further include a first electrode connected to the source.

According to another aspect of the disclosure, a method of manufacturing an amorphous boron nitride film includes cleaning a substrate, inserting the substrate into a chamber, and heating the substrate by raising and maintaining a temperature inside the chamber to within a range of about 250° C. to about 400° C., and depositing a material, for the amorphous boron nitride film, multiple times using an atomic layer deposition (ALD) method.

The material for the amorphous boron nitride film includes a precursor and a reactant, and the ALD method may include injecting a precursor, performing a first purging process, injecting a reactant, and performing a second purging process.

In the injecting of the precursor, a precursor containing triethylboron may be used.

In the injecting the reactant, NH₃ plasma may be used.

In the performing of the first purging process and the second purging process, argon gas may be used.

The method may further include, after the depositing of the amorphous boron nitride film, lowering the temperature of the chamber.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a semiconductor device according to at least one example embodiment;

FIGS. 2 and 3 are diagrams illustrating a semiconductor device according to at least one example embodiment;

FIG. 4 is a diagram illustrating a semiconductor device according to at least one example embodiment;

FIG. 5 is a diagram illustrating a semiconductor device according to at least one example embodiment;

FIG. 6 is a flowchart of a method of manufacturing an amorphous boron nitride film, according to at least one example embodiment;

FIG. 7A is a graph showing a growth rate of an amorphous boron nitride film according to precursor exposure time;

FIG. 7B is a graph showing a growth rate of an amorphous boron nitride film according to reactant exposure time;

FIG. 7C is a graph showing a growth rate of an amorphous boron nitride film according to growth temperature;

FIG. 7D is a graph showing a thickness of an amorphous boron nitride film as atomic layer deposition is repeated;

FIG. 7E is a graph showing a growth rate of an amorphous boron nitride film according to the flow rate of a reactant;

FIGS. 8A to 8C are component analysis graphs for an amorphous boron nitride film according to at least one example embodiment;

FIG. 9A is a graph showing the Raman spectrum of an amorphous boron nitride film according to at least one example embodiment;

FIG. 9B is a graph showing the X-ray diffraction (XRD) spectrum of an amorphous boron nitride film according to at least one example embodiment;

FIG. 10A is a scanning electron microscope (SEM) diagram showing the thickness of an amorphous boron nitride film according to at least one example embodiment;

FIG. 10B is a graph showing a dielectric constant of an amorphous boron nitride film according to at least one example embodiment;

FIG. 11 is a block diagram illustrating an electronic system according to at least one example embodiment; and

FIG. 12 is a block diagram of an electronic system according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the attached drawings, a semiconductor device including an amorphous boron nitride film and a method of manufacturing the amorphous boron nitride film will be described in detail. In the following drawings, the same reference numerals refer to the same components, and the size of each component in the drawings may be exaggerated for clarity and convenience of explanation. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y. Meanwhile, the embodiments described below are merely illustrative, and various modifications are possible from these embodiments.

It will also be understood that when an element is referred to as being “on” or “above” another element, the element may be in direct contact with the other element or other intervening elements may be present. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms include the plural forms unless the context clearly indicates otherwise. It should be understood that, when a part “comprises” or “includes” an element in the specification, unless otherwise defined, other elements are not excluded from the part and the part may further include other elements.

The use of the terms “a” and “an” and “the” and similar referents in the context of describing the disclosure are to be construed to cover both the singular and the plural. The steps of all methods described herein can be performed in any suitable order unless otherwise indicated herein or otherwise clearly contradicted by context.

The connecting lines, or connectors shown in the various figures presented are intended to represent examples of functional relationships and/or physical or logical couplings between the various elements. It should be noted that many alternative or additional functional relationships, physical connections or logical connections may be present in a practical device.

The use of any and all examples, or exemplary language provided herein, is intended merely to better illuminate the disclosure and does not pose a limitation on the scope of the disclosure unless otherwise claimed.

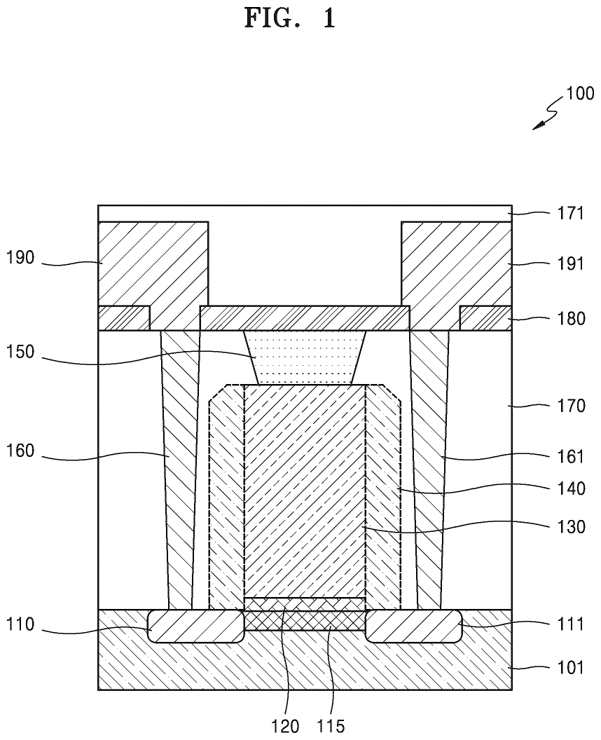

FIG. 1 is a diagram illustrating a semiconductor device according to at least one example embodiment. The semiconductor device shown in FIG. 1 may be a transistor device.

Referring to FIG. 1, a semiconductor device 100 may include a semiconductor substrate 101, a source 110 and a drain 111 provided horizontally spaced apart from each other on the semiconductor substrate 101, a channel layer 115 provided between the source 110 and the drain 111, a gate insulating layer 120 provided on the channel layer 115, a gate electrode 130 provided on the gate insulating layer 120, and a spacer 140 surrounding the gate electrode 130.

The semiconductor substrate 101 may include various materials. For example, the semiconductor substrate 101 may include a semiconductor material such as silicon (Si), germanium (Ge), silicon germanium (SiGe), silicon carbide (SiC), gallium arsenide (GaAs), indium arsenide (InAs), or indium phosphide (InP), and/or an insulating material such as silicon oxide, silicon nitride, or silicon oxynitride. Additionally, the semiconductor substrate 101 may include a silicon on insulator (SOI) substrate.

The channel layer 115 is an area between the source 110 and the drain 111 and is electrically connected to the source 110 and the drain 111. The source 110 may be electrically connected to or in contact with one end of the channel layer 115, and the drain 111 may be electrically connected to or in contact with the other end of the channel layer 115. The channel layer 115 may be defined as and/or include an area between the source 110 and the drain 111 in the semiconductor substrate 101 and may include the semiconductor material.

In at least some embodiments, the channel layer 115, the source 110. and the drain 111 may be formed by doping impurities into respective regions of the semiconductor substrate 101. For example, the source 110 and the drain 111 may be doped with n-type or p-type impurities. For example, the source 110 and the drain 111 may be formed by doping a portion of the semiconductor substrate 101 with one of phosphorus (P), arsenic (As), antimony (Sb), and boron (B).

The channel layer 115 may also be implemented as a separate material layer (e.g., a thin film). In this case, the channel layer 115 may include one or more of Si, Ge, SiGe, Group III-V semiconductor, oxide semiconductor, nitride semiconductor, oxynitride semiconductor, two-dimensional material (2D material), quantum dots, organic semiconductors, and/or the like. The oxide semiconductor may include, for example, InGaZnO. The two-dimensional material may include, for example, transition metal dichalcogenide (TMD) or graphene. The quantum dots may include, for example, colloidal QDs or nanocrystal structures.

The gate electrode 130 may be disposed over the semiconductor substrate 101 and apart from the semiconductor substrate 101 and face the channel layer 115. The gate electrode 130 may include a conductive material, such as at least one of metal, metal nitride, metal carbide, and/or polysilicon. The metal may include, for example, at least one of aluminum (Al), tungsten (W), molybdenum (Mo), titanium (Ti), tantalum (Ta), and/or the like. The metal nitride film may include, for example, one or more of a titanium nitride film (TiN film), a tantalum nitride film (TaN film), and/or the like. The metal carbide may include, for example, one or more of metal carbides doped with (or containing) aluminum or silicon. The metal carbide may include, for example, TiAlC, TaAlC, TiSiC, TaSiC, and/or the like.

The gate electrode 130 may have a structure in which a plurality of materials are stacked. The gate electrode 130 may have, for example, a stacked structure of a metal nitride layer/metal layer, such as TiN/Al, or a stacked structure of a metal nitride layer/metal carbide layer/metal layer, such as TiN/TiAlC/W. The materials used for the gate electrode 130 and described above are merely examples and are not limited thereto.

The gate insulating layer 120 may be further provided between the semiconductor substrate 101 and the gate electrode 130. The gate insulating layer 120 may be provided on the channel layer 115. The gate insulating layer 120 may include an electrically insulating material (hereafter an “insulator”), such as a least one of silicon oxide, silicon nitride, aluminum oxide, hafnium oxide, zirconium oxide, or a two-dimensional insulator. The two-dimensional insulator may include, for example, hexagonal boron nitride (h-BN).

The spacer 140 may be provided to contact a side surface of the gate electrode 130. The spacer 140 may be provided to surround the gate electrode 130. The spacer 140 may prevent cross-talk between the source 110, the drain 111, and the gate electrode 130 and may include an insulator.

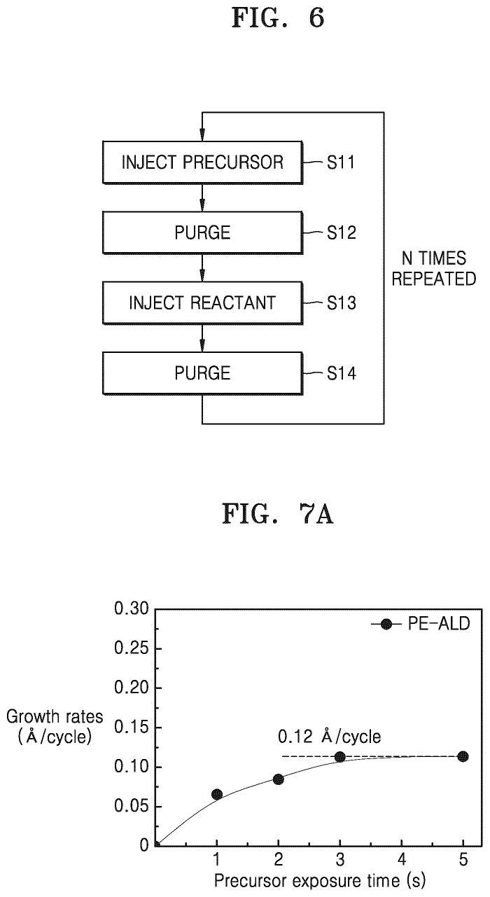

Parasitic capacitance may occur between the source 110 and the gate electrode 130 and/or between the gate electrode 130 and the drain 111. To reduce the parasitic capacitance, the spacer 140 may include an amorphous boron nitride film. More specifically, since amorphous boron nitride film may have a low dielectric constant and a magnitude of a capacitance directly corresponds to a magnitude of a dielectric constant, the amorphous boron nitride film may reduce the capacitance between the source 110 and the gate electrode 130 and/or between the gate electrode 130 and the drain 111. For example, the dielectric constant of the amorphous boron nitride film may be about 2.0 or less. An atomic ratio (B/N ratio) of boron (B) and nitrogen (N) in the amorphous boron nitride film may be about 1:1. The amorphous boron nitride film may also include carbon (C) and/or oxygen (O) at a lesser percentage than either the B and/or N. For example, the carbon (C) content (atomic %) may be 5 at % or less, and the boron-oxygen (B—O) content (atomic %) may be less than 1 at %. A manufacturing method of the amorphous boron nitride film will be described later with reference to FIG. 6.

A contact gate 150 may be provided on the gate electrode 130. The contact gate 150 may be in contact with an etch stop layer 180. The contact gate 150 may penetrate an interlayer insulating layer 170 and be connected to the gate electrode 130. A bottom surface of the contact gate 150 may be in contact with a top surface of the gate electrode 130.

The interlayer insulating layer 170 may be provided on the semiconductor substrate 101. The interlayer insulating layer 170 may be provided to contact the gate electrode 130, the spacer 140, and the contact gate 150. The interlayer insulating layer 170 may include, for example, an insulator such as silicon oxide, but is not limited thereto.

A plurality of conductive plugs 160 and 161 may be provided on the source 110 and the drain 111. The plurality of conductive plugs 160 and 161 may be provided to penetrate the interlayer insulating layer 170. The plurality of conductive plugs 160 and 161 may pass through the interlayer insulating layer 170 and extend in a direction perpendicular to the semiconductor substrate 101 forming electrical paths to the source 110 and the drain 111, respectively. The plurality of conductive plugs 160 and 161 may include a conductive material, for example, at least one of molybdenum (Mo), copper (Cu), tungsten (W), cobalt (Co), ruthenium (Ru), manganese (Mn), titanium (Ti), tantalum (Ta), aluminum (Al), and/or the like.

An intermetallic insulating layer 171 may be provided over the interlayer insulating layer 170 to be spaced apart from the interlayer insulating layer 170. The intermetallic insulating layer 171 may include, for example, a silicon oxide film, but is not limited thereto.

The etch stop layer 180 may be provided between the interlayer insulating layer 170 and the intermetallic insulating layer 171. The etch stop layer 180 may include a metal oxide film or a metal nitride film. The metal oxide film or the metal nitride film may include at least one metal selected from Al, Zr, Y, Hf, or Mo. The etch stop layer 180 may include, for example, aluminum oxide, hafnium oxide, hafnium zirconium oxide, aluminum nitride, hafnium nitride, or hafnium zirconium nitride.

A plurality of contacts 190 and 191 may be disposed on the source 110 and the drain 111. The plurality of contacts 190 and 191 may be in contact with the conductive plugs 160 and 161 that penetrate the interlayer insulating layer 170, respectively.

The plurality of contacts 190 and 191 may include a conductive and/or metal material. The plurality of contacts 190 and 191 may include, for example, at least one of molybdenum (Mo), copper (Cu), tungsten (W), cobalt (Co), ruthenium (Ru), manganese (Mn), titanium (Ti), tantalum (Ta), or aluminum (Al), but is not limited thereto.

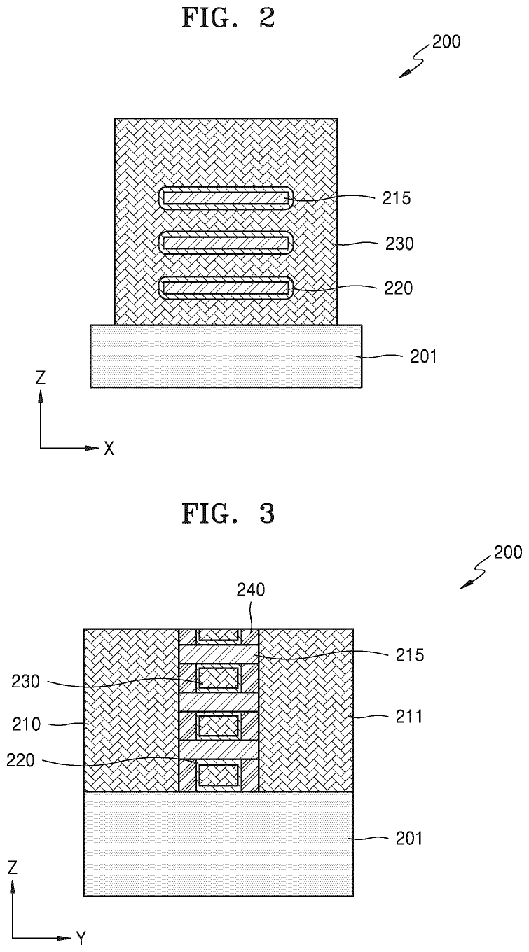

FIGS. 2 and 3 are diagrams illustrating a semiconductor device according to at least one example embodiment. The semiconductor device of FIGS. 2 and 3 may be a gate-all-around field-effect transistor (GAA FET) device.

Referring to FIGS. 2 and 3, a semiconductor device 200 may include a substrate 201, a source electrode 210 and a drain electrode 211 provided on the substrate 201 to be horizontally spaced apart from each other, a channel layer 215 and a gate electrode 230 provided between the source electrode 210 and the drain electrode 211, a gate insulating layer 220 provided on the gate electrode 230, and a spacer 240 provided to surround the gate electrode 230.

The substrate 201 may include, for example, a semiconductor material such as silicon (Si), germanium (Ge), silicon germanium (SiGe), silicon carbide (SiC), gallium arsenide (GaAs), indium arsenide (InAs), or indium phosphide (InP), and/or may include an insulator such as silicon oxide, silicon nitride, or silicon oxynitride. Additionally, the semiconductor substrate 201 may include a SOI substrate.

The channel layer 215 may include a semiconductor material, and may extend along a direction parallel to the semiconductor substrate 201. For example, the channel layer 215 may have a nanowire shape extending along a direction or a nanosheet shape extending along a plane. There may be a plurality of channel layers 215. The plurality of channel layers 215 may be arranged apart from each other in a direction perpendicular to the semiconductor substrate 201 (Z-direction) and may be referred to as stacked on the substrate 201. In other words, channel layers 215 adjacent to each other may be arranged separately from each other along the first direction (Z-direction). The channel layer 215 may directly contact the source electrode 210 and the drain electrode 211. However, the disclosure is not limited thereto, and the channel layer 215 may be connected to the source electrode 210 and the drain electrode 211 through another medium.

The gate insulating layer 220 may be arranged to surround the channel layer 215. The gate electrode 230, which will be described later, and the source electrode 210 and the drain electrode 211 may be insulated by the gate insulating layer 220. The gate insulating layer 220 may include an insulator, such as at least one of silicon oxide, silicon nitride, aluminum oxide, hafnium oxide, zirconium oxide, a two-dimensional insulator, and/or the like. The two-dimensional insulator may include, for example, hexagonal boron nitride (h-BN).

The gate electrode 230 may be disposed on the gate insulating layer 220 and may be provided to surround the channel layer 215. As an example, the gate electrode 230 may be arranged to surround the entire side of the channel layer 215. Accordingly, the semiconductor device 200 may be provided as a gate-all-around field-effect transistor (GAA FET). The gate electrode 230 may include a conductive material, for example, one or more of metal, metal-carbide, metal-nitride, metal-silicide, metal-silicon-nitride, silicon, and graphene-based materials. The gate electrode 230 may have a certain work function. A threshold voltage of a field-effect transistor structure according to an example may be adjusted using the work function of the gate electrode 230.

The spacer 240 may be provided between the source electrode 210 and the gate electrode 230 and between the drain electrode 211 and the gate electrode 230. The spacer 240 may be provided to contact the gate insulating layer 220 provided to surround the gate electrode 230. The spacer 240 may prevent cross-talk between the source electrode 210, the drain electrode 211, and the gate electrode 230.

Parasitic capacitance may occur between the source electrode 210 and the gate electrode 230 and between the gate electrode 230 and the drain electrode 211. To reduce parasitic capacitance, the spacer 240 may include an amorphous boron nitride film. An amorphous boron nitride film may have a low dielectric constant. The dielectric constant of the amorphous boron nitride film may be about 2.0 or less. An atomic ratio (B/N ratio) of boron (B) and nitrogen (N) in the amorphous boron nitride film may be about 1:1. The amorphous boron nitride film may also include carbon (C) and/or oxygen (O) at a lesser percentage than either the B and/or N. For example, the carbon (C) content (atomic %) may be 5 at % or less, and the B—O content (atomic %) may be less than 1 at %.

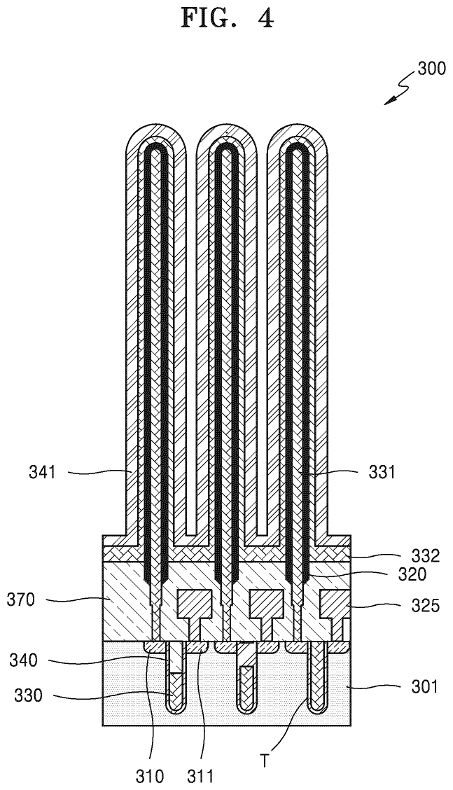

FIG. 4 is a diagram illustrating a semiconductor device according to at least one example embodiment. The semiconductor device of FIG. 4 may be a dynamic random-access memory (DRAM) device having a buried channel array transistor (BCAT) structure.

Referring to FIG. 4, a semiconductor device 300 may include a semiconductor substrate 301, a source 310 and a drain 311 provided horizontally spaced apart from each other on the semiconductor substrate 301, a spacer 340 covering a lower surface and a sidewall of a trench T provided between the source 310 and the drain 311, and a gate electrode 330 that is arranged in contact with the spacer 340 inside the trench T and fills a portion of the trench T.

The semiconductor substrate 301 may include a semiconductor material, such as silicon, single-crystalline silicon, polysilicon, amorphous silicon, silicon germanium, single-crystalline silicon germanium, polycrystalline silicon germanium, carbon-doped silicon, or a combination thereof, and/or an insulating material such as silicon oxide, silicon nitride, or silicon oxynitride. Additionally, the semiconductor substrate 301 may include a silicon on insulator (SOI) substrate. The semiconductor substrate 301 may include a Group III-V semiconductor substrate, for example, a compound semiconductor substrate such as gallium arsenide (GaAs).

A plurality of trenches T formed by etching a portion of the semiconductor substrate 301 in a vertical direction may be disposed in the semiconductor substrate 301. The source 310 and the drain 311 formed to be horizontally spaced apart from each other by the trench T may be disposed in the semiconductor substrate 301. The source 310 and the drain 311 may be arranged side by side, facing an upper region of the trench T in a horizontal direction. For example, upper surfaces of the source 310 and the drain 311 and an upper surface of the semiconductor substrate 301 may be disposed on the same plane as each other. Additionally, lower surfaces of the source 310 and the drain 311 may be located higher than a lower surface of the trench T1. Additionally, the source 310 and the drain 311 may contact the sidewall of the trench T.

The source 310 and the drain 311 may be formed by doping impurities into a partial region of the semiconductor substrate 301. For example, by doping a portion of the semiconductor substrate 301 with one of phosphorus (P), arsenic (As), antimony (Sb), and boron (B), the source 310 and the drain 311 may be formed.

The gate electrode 330 and the spacer 340 may be embedded in the trench T. The gate electrode 330 may partially fill the inside of the trench T.

The gate electrode 330 may include at least one of metal, metal nitride, metal carbide, and polysilicon. The metal may include, for example, at least one of aluminum (Al), tungsten (W), molybdenum (Mo), titanium (Ti), and tantalum (Ta). The metal nitride film may include, for example, one or more of a titanium nitride film (TiN film) and a tantalum nitride film (TaN film). The metal carbide may include, for example, one or more of metal carbides doped with (or containing) aluminum or silicon. The metal carbide may include, for example, TiAlC, TaAlC, TiSiC or TaSiC. The gate electrode 330 may be connected to a word line, and a bit line 325 may be provided on the drain 311.

The spacer 340 may be arranged to contact the lower surface and the sidewall of the trench T. The gate electrode 330 may partially fill the inside of the trench T, and the spacer 340 may be disposed between the semiconductor substrate 301 and the gate electrode 330 and surround the gate electrode 330. Accordingly, the gate electrode 330 may not directly contact the lower surface and the sidewall of the trench T.

Parasitic capacitance may occur between the source 310 and the gate electrode 330 and between the gate electrode 330 and the drain 311. To reduce parasitic capacitance, the spacer 340 may include an amorphous boron nitride film. An amorphous boron nitride film may have a low dielectric constant. The dielectric constant of the amorphous boron nitride film may be about 2.0 or less. An atomic ratio (B/N ratio) of boron (B) and nitrogen (N) in the amorphous boron nitride film may be about 1:1. The amorphous boron nitride film may also include carbon (C) and/or oxygen (O) at a lesser percentage than either the B and/or N. For example, the carbon (C) content (atomic %) may be 5 at % or less, and the B—O content (atomic %) may be less than 1 at %.

An interlayer insulating layer 370 may be provided on the semiconductor substrate 301. The interlayer insulating layer 370 may be provided to contact the gate electrode 330 and the spacer 340. The interlayer insulating layer 370 may include an insulator, for example, a silicon oxide film, but is not limited thereto.

A first electrode 331 may be provided on the source 310. The first electrode 331 may be provided to penetrate the interlayer insulating layer 370. The first electrode 331 may pass through the interlayer insulating layer 370 and extend in a direction perpendicular to the semiconductor substrate 301. The first electrode 331 may include metal, metal nitride, metal oxide, or a combination thereof. The first electrode 331 may include, for example, a metal such as titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb).

An insulating layer 320 surrounding the first electrode 331 may be provided. The insulating layer 320 may be a high-k dielectric layer which has a high dielectric constant. The insulating layer 320 may include silicon oxide, silicon nitride, aluminum oxide, hafnium oxide, zirconium oxide, or a two-dimensional insulator. The two-dimensional insulator may include, for example, hexagonal boron nitride (h-BN).

A second electrode 332 may be provided on the interlayer insulating layer 370 and surround the insulating layer 320. The second electrode 332 may include the same material as the first electrode 331. The second electrode 332 may include metal, metal nitride, metal oxide, or a combination thereof. The second electrode 332 may include, for example, a metal such as titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb).

A capping spacer 341 surrounding the second electrode 332 may be provided. The capping spacer 341 may include an amorphous boron nitride film. An amorphous boron nitride film may have a low dielectric constant. The dielectric constant of the amorphous boron nitride film may be about 2.0 or less. An atomic ratio (B/N ratio) of boron (B) and nitrogen (N) in the amorphous boron nitride film may be about 1:1. The amorphous boron nitride film may also include carbon (C) and/or oxygen (O) at a lesser percentage than either the B and/or N. For example, the carbon (C) content (atomic %) may be 5 at % or less, and the B—O content (atomic %) may be less than 1 at %.

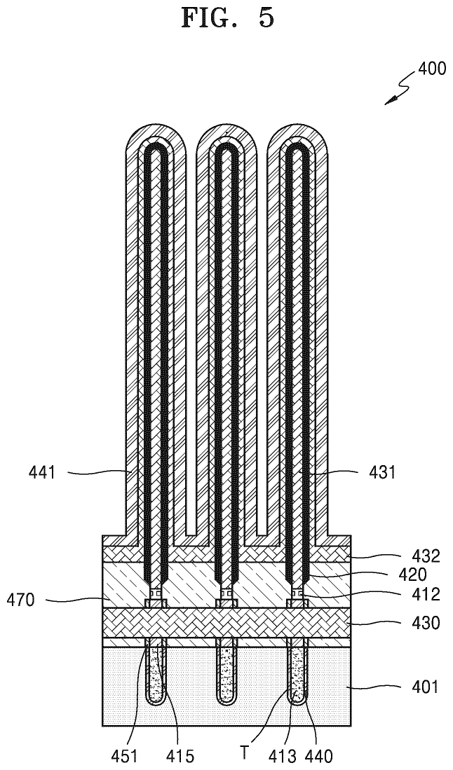

FIG. 5 is a diagram illustrating a semiconductor device according to at least one example embodiment. The semiconductor device of FIG. 5 may be a DRAM device having a vertical channel array transistor (VCAT) structure.

Referring to FIG. 5, a semiconductor device 400 may include a semiconductor substrate 401, a spacer 440 covering a lower surface and a sidewall of the trench T provided in the semiconductor substrate 401, a drain 413 that is arranged to be in contact with the spacer 440 in the trench T and fills a portion of the trench T, a source 412 arranged apart from the drain 413 in a direction perpendicular to the semiconductor substrate 401, and a channel layer 415 provided between the source 412 and the drain 413.

The semiconductor substrate 401 may include a semiconductor material, such as silicon, single-crystalline silicon, polysilicon, amorphous silicon, silicon germanium, single-crystalline silicon germanium, polycrystalline silicon germanium, carbon-doped silicon, and/or a combination thereof, and/or an insulating material such as silicon oxide, silicon nitride, or silicon oxynitride. Additionally, the semiconductor substrate 401 may include a silicon on insulator (SOI) substrate. The semiconductor substrate 401 may include a Group III-V semiconductor substrate, for example, a compound semiconductor substrate such as gallium arsenide (GaAs).

A plurality of trenches T formed by etching a portion of the semiconductor substrate 401 in a vertical direction may be disposed on the semiconductor substrate 401. The drain 413 and the spacer 440 may be embedded in the trench T. The spacer 440 may be arranged to contact a lower surface and a sidewall of the trench T. The drain 413 fills the inside of the trench T, and the spacer 440 may be disposed between the semiconductor substrate 401 and the drain 413 and surround the drain 413. Accordingly, the drain 413 may not directly contact the lower surface and the sidewall of the trench T.

The spacer 440 may include an amorphous boron nitride film. An amorphous boron nitride film may have a low dielectric constant. The dielectric constant of the amorphous boron nitride film may be about 2.0 or less. An atomic ratio (B/N ratio) of boron (B) and nitrogen (N) in the amorphous boron nitride film may be about 1:1. The amorphous boron nitride film may also include carbon (C) and/or oxygen (O) at a lesser percentage than either the B and/or N. For example, the carbon (C) content (atomic %) may be 5 at % or less, and the B—O content (atomic %) may be less than 1 at %.

A gate electrode 430 may be provided on the semiconductor substrate 401. The gate electrode 430 may include at least one of metal, metal nitride, metal carbide, and polysilicon. The metal may include, for example, at least one of aluminum (Al), tungsten (W), molybdenum (Mo), titanium (Ti), and tantalum (Ta). The metal nitride film may include, for example, one or more of a titanium nitride film (TiN film) and a tantalum nitride film (TaN film). The metal carbide may include, for example, one or more of metal carbides doped with (or containing) aluminum or silicon. The metal carbide may include, for example, TiAlC, TaAlC, TiSiC or TaSiC. The gate electrode 430 may be connected to a word line, and the drain 413 may be connected to the word line.

An interlayer insulating layer 470 may be provided on the semiconductor substrate 401. The interlayer insulating layer 470 may be provided to contact the gate electrode 430. The interlayer insulating layer 470 may include an insulator, for example, a silicon oxide film, but is not limited thereto.

The channel layer 415 may be provided on the drain 413 and the source 412 may be provided on the channel layer 415. The channel layer 415 may extend along a direction parallel to the semiconductor substrate 401. There may be a plurality of channel layers 415. The channel layer 415 may directly contact the source 412 and the drain 413. However, the disclosure is not limited thereto, and the channel layer 415 may also be connected to the source 412 and the drain 413 through another medium.

The channel layer 415 may be surrounded by a gate insulating layer 451. The gate insulating layer 451 may be a high-k dielectric layer which has a high dielectric constant. The gate insulating layer 451 may include, for example, at least one of metal-oxide containing Hf or Zr, or metal-oxide-nitride containing Hf or Zr, or the above materials doped with Ti, Ta, Al, or lanthanides.

A first electrode 431 may be provided on the source 412. The first electrode 431 may extend in a direction perpendicular to the semiconductor substrate 401. The first electrode 431 may include metal, metal nitride, metal oxide, or a combination thereof. The first electrode 431 may include, for example, a metal such as titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb).

An insulating layer 420 surrounding the first electrode 431 may be provided. The insulating layer 420 may be a high-k dielectric layer which has a high dielectric constant. The gate insulating layer 420 may include, for example, an insulator, such as silicon oxide, silicon nitride, aluminum oxide, hafnium oxide, zirconium oxide, a two-dimensional insulator, and/or the like. The two-dimensional insulator may include, for example, hexagonal boron nitride (h-BN).

A second electrode 432 may be provided on the interlayer insulating layer 470 and surround the gate insulating layer 420. The second electrode 432 may include the same and/or a similar material as the first electrode 431. The second electrode 432 may include, for example, metal, metal nitride, metal oxide, or a combination thereof. The second electrode 432 may include, for example, a metal such as titanium (Ti), nickel (Ni), aluminum (Al), tantalum (Ta), tungsten (W), platinum (Pt), palladium (Pd), gold (Au), iridium (Ir), rhodium (Rh), molybdenum (Mo), vanadium (V), or niobium (Nb). The insulating layer 420 may electrically insulate the first and second electrodes 431 and 432, thereby forming a capacitor.

A capping spacer 441 surrounding the second electrode 432 may be provided. The capping spacer 341 may include an amorphous boron nitride film. An amorphous boron nitride film may have a low dielectric constant. The dielectric constant of the amorphous boron nitride film may be about 2.0 or less. An atomic ratio (B/N ratio) of boron (B) and nitrogen (N) in the amorphous boron nitride film may be about 1:1. The amorphous boron nitride film may also include carbon (C) and/or oxygen (O) at a lesser percentage than either the B and/or N. For example, the carbon (C) content (atomic %) may be 5 at % or less, and the B—O content (atomic %) may be less than 1 at %.

FIG. 6 is a flowchart of a method of manufacturing an amorphous boron nitride film, according to at least one example embodiment.

Referring to FIG. 6, a material of the amorphous boron nitride film may be repeatedly deposited multiple times using an atomic layer deposition (ALD) method.

The method of manufacturing an amorphous boron nitride film may include cleaning a semiconductor substrate, inserting the semiconductor substrate into a chamber, raising and maintaining the temperature inside the chamber to about 250° C. to about 400° C., repeatedly depositing the material of the amorphous boron nitride film multiple times by using ALD, and lowering the temperature of the chamber.

The depositing of the amorphous boron nitride film may include injecting a precursor into a chamber (S11), a purging operation (S12), injecting a reactant into the chamber to make the reactant react with the precursor (S13), and a purging operation (S14). Operations S11, S12, S13, and S14 may be repeated n times (wherein n is a natural number). Operations S11, S12, S13, and S14 may be repeated, for example, from 1 to 100 times. Operations S11, S12, S13, and S14 may be repeated, for example, from 1 to 50 times.

The precursor used in operation S11 may include, for example, triethylboron ((Et) 3B). In operation S11, the precursor may be exposed to the semiconductor substrate for, for example, about 1 second to about 5 seconds. The (Et) 3B precursor may be supplied in a range of about 0.1 Torr to about 1 Torr in partial pressure units. In the purging operations (S12, S14), an excess precursor and reaction by-products inside the chamber may be removed by flowing Ar gas into the chamber. A flow rate of Ar gas may be about 100 sccm to about 300 sccm. The purge operations (S12, S14) may be maintained for, for example, about 1 second to about 10 seconds. The reactant used in operation S13 may include, for example, NH₃. The reactant injection operation may include an NH₃ plasma process. In other words, the depositing of the spacer of the amorphous boron nitride film may be performed by a plasma enhanced (PE) atomic layer deposition method. The flow rate of NH₃ gas may be about 30 sccm to about 500 sccm. RF plasma power may be about 30 W to about 300 W. Operation S13 may be performed, for example, from about 1 second to about 10 seconds. In at least some embodiments, depositing of the amorphous boron nitride film may include additional elements being injected. For example, as part of the injection operations (S11, S13) and/or as separate injections.

Before the repeatedly depositing the amorphous boron nitride film material multiple times using the ALD method, the cleaning of the semiconductor substrate, the inserting of the semiconductor substrate in a chamber, and raising and maintaining the temperature inside the chamber to about 250° C. to about 400° C. may be preceded.

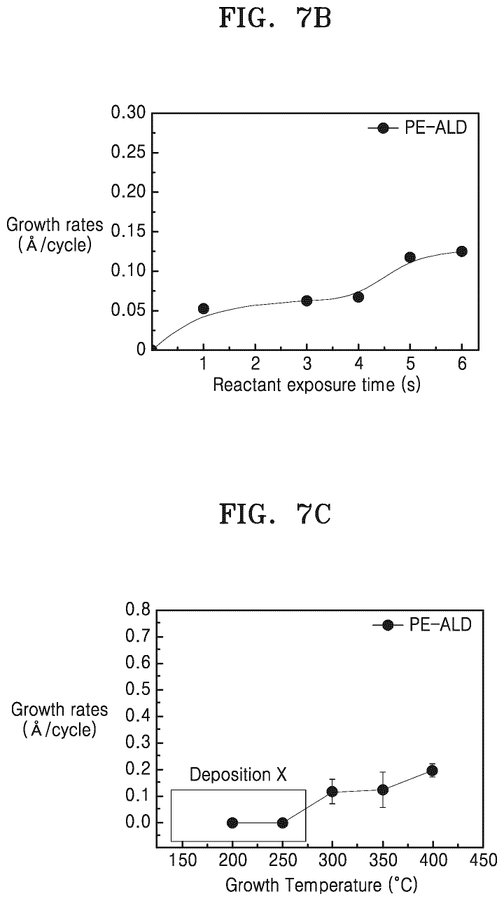

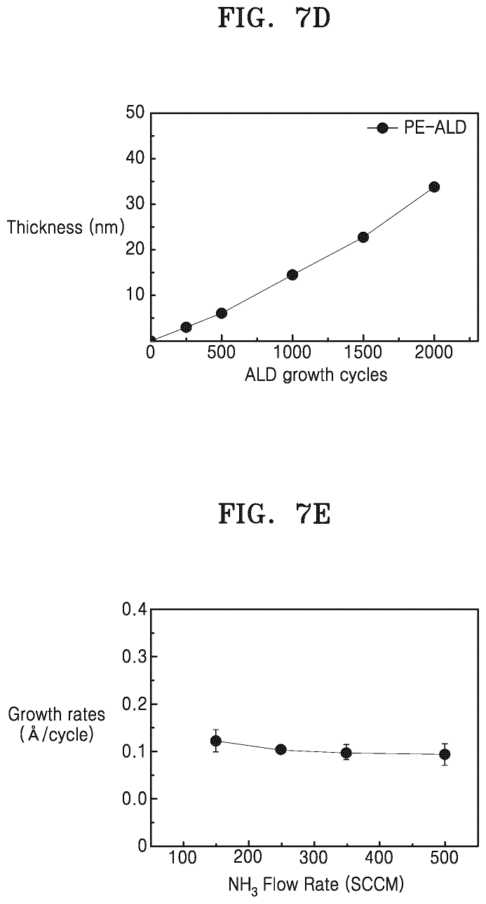

An amorphous boron nitride film according to at least one example embodiment was obtained by putting triethylboron and NH₃ gas at a flow rate of 500 sccm on a silicon substrate at 350° C. and making them react with 300 W plasma. The atomic ratio between B atoms and N atoms (B/N ratio) of the amorphous boron nitride film according to the above embodiment was about 1:1. The amorphous boron nitride film may also include carbon (C) and/or oxygen (O) at a lesser percentage than either the B and/or N. For example, the C content (atomic %) was 5 at % or less, and the B—O content (atomic %) was 1 at % or less, and the amorphous boron nitride film had a low dielectric constant of 2.0 or less. FIGS. 7A to 10B are diagrams showing measurements of the characteristics of an amorphous boron nitride film according to the above embodiment.

FIG. 7A is a graph showing the growth rate of an amorphous boron nitride film according to precursor exposure time.

Referring to FIG. 7A, as the precursor exposure time increases, the growth rate of the amorphous boron nitride film increases and reaches saturation at about 0.12 Å/cycle. This indicates that atomic layer deposition may be properly achieved through saturation of the growth rate of the thin film.

FIG. 7B is a graph showing the growth rate of an amorphous boron nitride film according to reactant exposure time.

Referring to FIG. 7B, as the reactant exposure time increases, the thin film growth rate increases and then reaches saturation. This indicates that atomic layer deposition may be properly achieved through saturation of the thin film growth rate.

FIG. 7C is a graph showing the growth rate of an amorphous boron nitride film according to growth temperature.

Referring to FIG. 7C, it can be seen that deposition does not occur at a growth temperature of 200° C. to 250° C. This indicates that an amorphous boron nitride film may be grown at a temperature of about 300° C. or higher.

FIG. 7D is a graph showing the thickness of an amorphous boron nitride film as atomic layer deposition is repeated.

Referring to FIG. 7D, it can be seen that the thickness of the amorphous boron nitride film increases linearly as atomic layer deposition is repeated. This indicates that atomic layer deposition may be properly performed.

FIG. 7E is a graph showing the growth rate of an amorphous boron nitride film according to the flow rate of a reactant.

Referring to FIG. 7E, it can be seen that even if the flow rate of the reactant increases, the growth rate of the amorphous boron nitride film saturates at about 0.1 Å/cycle.

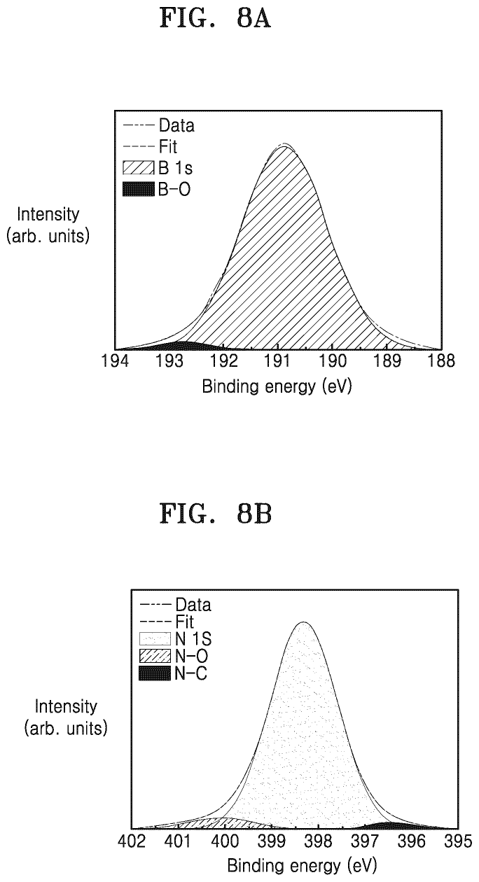

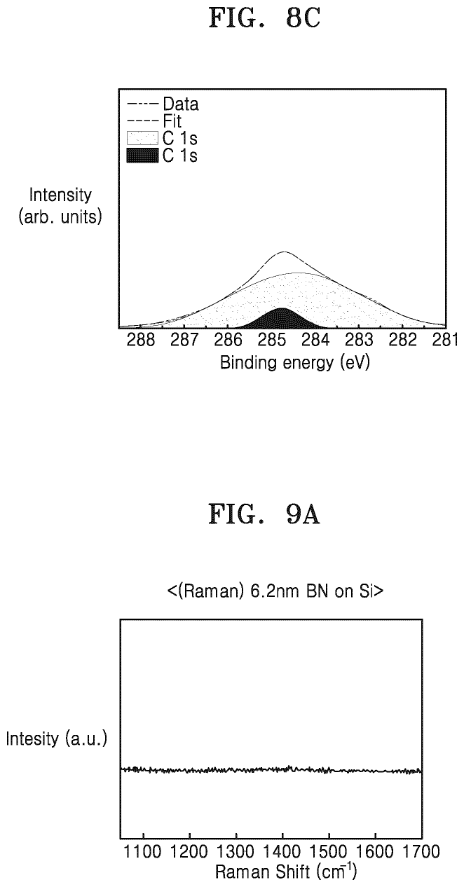

FIGS. 8A to 8C are component analysis graphs of an amorphous boron nitride film according to at least one example embodiment.

Referring to FIG. 8A, the boron (B) content (atomic %) of the amorphous boron nitride film produced under atomic layer deposition conditions according to the embodiment is 43.3%, and the boron-oxygen (B—O) content (atomic %) is 1%. B—O indicates a state in which residual B that is not bonded to N is bonded to O. The content of each element was calculated by dividing the area of the component spectrum of each element by the area ratio of all components by using X-ray photoelectron spectroscopy (XPS).

Referring to FIG. 8B, the nitrogen (N) content (atomic %) of the amorphous boron nitride film produced under the atomic layer deposition conditions according to the embodiment is 40.6%, and the nitrogen-oxygen (N—O) content (atomic %) is 2.2. %, and the nitrogen-carbon (N—C) content (atomic %) is 1.1%. N—O indicates a state in which residual N that has not bonded to B is bonded to O, and N—C indicates a state in which residual N that is not bonded to B is bonded to C.

Referring to FIG. 8C, it can be seen that the carbon (C) content (atomic %) of the amorphous boron nitride film produced under the atomic layer deposition conditions according to the embodiment is 4.2%.

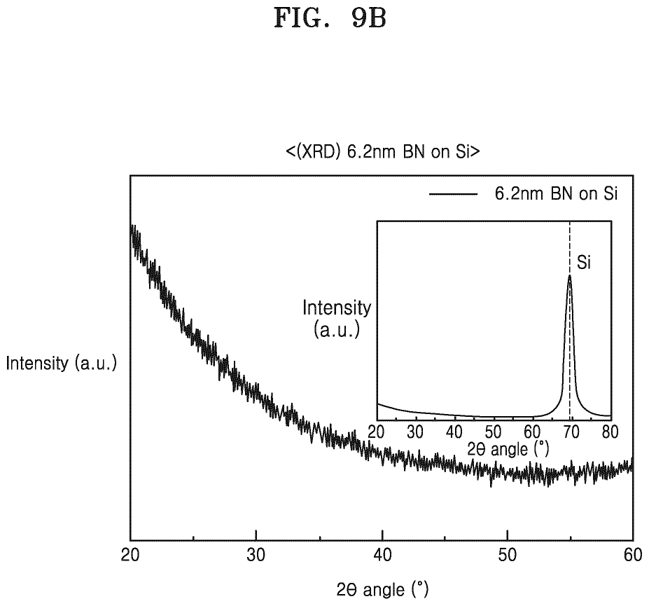

FIG. 9A is a graph showing the Raman spectrum of an amorphous boron nitride film according to at least one example embodiment.

Referring to FIG. 9A, the amorphous boron nitride film does not have a phonon scattering signal in a wavelength band of 1300 cm⁻¹ to 1400 cm⁻¹ of the Raman spectrum. An absorption peak in the 1300 cm⁻¹-1400 cm⁻¹ wavelength range of the Raman spectrum of the amorphous boron nitride film is known as the phonon scattering signal of the sp² BN (hexagonal BN) structure, and since the amorphous boron nitride film according to the present embodiment does not have the absorption peak, the amorphous boron nitride film has no crystals.

FIG. 9B is a graph showing the X-ray diffraction (XRD) spectrum of an amorphous boron nitride film according to at least one example embodiment.

Referring to FIG. 9B, during XRD analysis of the amorphous boron nitride film, there was no peak at 2θ=30°. Since the amorphous boron nitride film according to the present embodiment does not have a peak, it can be seen that the amorphous boron nitride film does not include crystals.

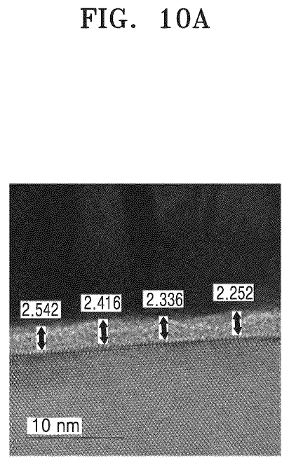

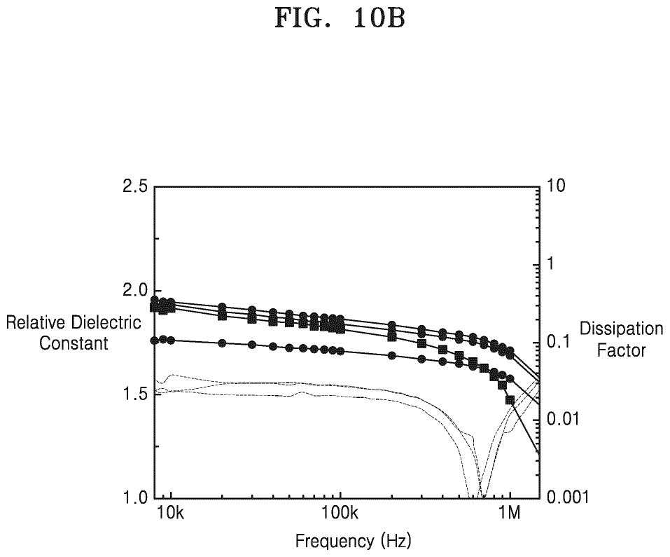

FIG. 10A is a scanning electron microscope (SEM) diagram showing the thickness of an amorphous boron nitride film according to at least one example embodiment.

Referring to FIG. 10A, it can be seen that a boron nitride film disposed between Pt and Si is in an amorphous form. In addition, it can be seen that the thickness of the amorphous boron nitride film is uniform in a range of about 2.2 nm to about 2.6 nm.

FIG. 10B is a graph showing a dielectric constant of an amorphous boron nitride film according to at least one example embodiment.

Using the sample of FIG. 10A, electrical properties were measured by connecting a Ru electrode to Pt. Referring to FIG. 10B, the dielectric constant of the boron nitride film was measured by using the thickness of the boron nitride film and the area of the Ru electrode thereabove through capacitance-voltage sweep measurement by applying alternating current (AC) voltage, and the dielectric constant of the amorphous boron nitride film was 2.0 or less. In addition, it was confirmed that a dissipation factor value of the boron nitride film according to the embodiment was 0.1 or less. This indicates that the amorphous boron nitride film according to the embodiment has a relatively low dielectric constant and may function as a reliable capacitor.

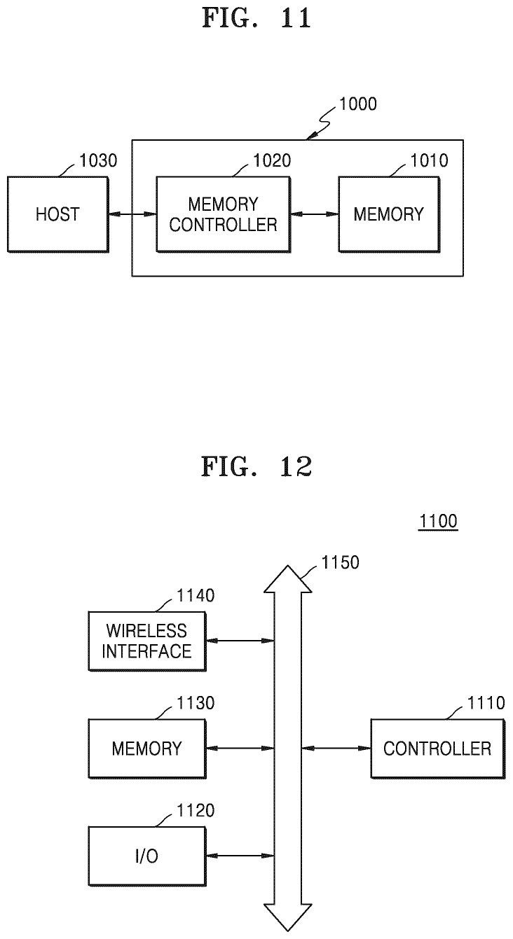

FIG. 11 is a block diagram illustrating an electronic system according to at least one example embodiment.

An electronic system 1000 includes a memory 1010 and a memory controller 1020. The memory controller 1020 may control the memory 1010 to read data from and/or write data to the memory 1010 in response to a request from a host 1030. At least one of the memory 1010 and the memory controller 1020 may include the semiconductor device according to the embodiments described above with reference to FIGS. 1 to 5.

FIG. 12 is a block diagram of an electronic system according to at least one example embodiment.

The electronic system 1100 may constitute a wireless communication device, or a device capable of transmitting and/or receiving information in a wireless environment. The electronic system 1100 may include a controller 1110, an input/output (I/O) device 1120, a memory 1130, and a wireless interface 1140, which are connected to each other through a bus 1150.

The controller 1110 may include at least one of a microprocessor, a digital signal processor, or a processing device similar to these. The input/output device 1120 may include at least one of a keypad, a keyboard, or a display. The memory 1130 may be used to store commands executed by the controller 1110. For example, the memory 1130 may be used to store user data. The electronic system 1100 may use the wireless interface 1140 to transmit/receive data through a wireless communication network. The wireless interface 1140 may include an antenna and/or a wireless transceiver. In some embodiments, the electronic system 1100 may be used in communication interface protocols of third generation communication systems such as code division multiple access (CDMA), global system for mobile communications (GSM), north American digital cellular (NADC), extended-time division multiple access (E-TDMA), and/or wide band code division multiple access (WCDMA). The electronic system 1100 may include the semiconductor device according to the embodiments described above with reference to FIGS. 1 to 5.

The semiconductor device according to the disclosure includes an amorphous boron nitride film spacer provided to surround a gate electrode, which reduces cross-talk. The semiconductor device including the amorphous boron nitride film and the manufacturing method of the amorphous boron nitride film have been described with reference to the embodiments shown in the drawings, but these are merely examples, and it will be obvious to those skilled in the art that various modifications and equivalents may be made therefrom. Therefore, the disclosed embodiments should be considered from an illustrative rather than a restrictive perspective. The scope of rights is indicated in the patent claims, not the foregoing description, and all differences within the equivalent scope should be interpreted as being included in the scope of rights.

According to the disclosed embodiment, the semiconductor device includes an amorphous boron nitride film spacer provided to surround a gate electrode, which reduces cross-talk.

A semiconductor device having a high-level difference structure may be implemented through the amorphous boron nitride film spacer according to the disclosed embodiment.

A low-dielectric constant amorphous boron nitride film may be manufactured using the method of manufacturing an amorphous boron nitride film according to the disclosed embodiment.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate;
a source and a drain horizontally spaced apart from each other on the substrate;
a channel layer between the source and the drain;
a gate electrode on the channel layer;
a gate insulating layer insulating the channel layer from the gate electrode; and
a spacer surrounding the gate electrode the spacer including an amorphous boron nitride film.

2. The semiconductor device of claim 1, wherein a dielectric constant of the amorphous boron nitride film is 2.0 or less.

3. The semiconductor device of claim 1, wherein a carbon content of the amorphous boron nitride film is 5 at % or less.

4. The semiconductor device of claim 1, wherein a boron-oxygen (B—O) content of the amorphous boron nitride film is 1 at % or less.

5. The semiconductor device of claim 1, wherein the channel layer is included in a plurality of channel layers, and
the plurality of channel layers are spaced apart from each other in a first direction, the first direction perpendicular to the substrate.

6. The semiconductor device of claim 5, wherein each of the plurality of channel layers has a nanowire shape extending in a second direction different from the first direction.

7. The semiconductor device of claim 5, wherein each of the plurality of channel layers has a nanosheet shape.

8. The semiconductor device of claim 1, further comprising:
conductive plugs respectively on the source and the drain.

9. The semiconductor device of claim 8, further comprising:
contacts respectively connected to the source and the drain through the conductive plugs.

10. A semiconductor device comprising:
a substrate, the substrate defining a trench;
a source and a drain horizontally spaced apart from each other on the substrate such that the trench is between the source and the drain;
a spacer covering a lower surface and a sidewall of the trench, the spacer including an amorphous boron nitride film; and
a gate electrode that is inside the trench, the gate electrode contacting the spacer and filling a portion of the trench.

11. The semiconductor device of claim 10, wherein a dielectric constant of the amorphous boron nitride film is 2.0 or less.

12. The semiconductor device of claim 10, wherein a carbon content of the amorphous boron nitride film is 5 at % or less.

13. The semiconductor device of claim 10, wherein a boron-oxygen (B—O) content of the amorphous boron nitride film is 1 at % or less.

14. The semiconductor device of claim 10, further comprising:
a first electrode connected to the source.

15. A method of manufacturing an amorphous nitride boron film, the method comprising:
cleaning a substrate;
inserting the substrate into a chamber,
heating the substrate by raising and maintaining a temperature inside the chamber to within of a range of about 250° C. to about 400° C.; and
depositing a material, for the amorphous boron nitride film, multiple times using an atomic layer deposition (ALD) method.

16. The method of claim 15, wherein the material for the amorphous boron nitride film includes a precursor and a reactant, and
wherein the ALD method comprises
injecting the precursor,
performing a first purging process,
injecting the reactant, and
performing a second purging process.

17. The method of claim 16, wherein the precursor includes triethylboron.

18. The method of claim 16, wherein the reactant includes NH₃ plasma.

19. The method of claim 16, wherein the first purging process and the second purging process includes purging using argon gas.

20. The method of claim 15, further comprising:
lowering the temperature of the chamber after the depositing of the amorphous boron nitride film.
